(19) United States
(12) Patent Application Publication
(10) Pub. No.: US 2016/0180787 A1
(43) Pub. Date: Jun. 23, 2016

(54) GATE DRIVING CIRCUIT AND DISPLAY DEVICE HAVING THE SAME

(71) Applicant: Samsung Display Co., Ltd., Yongin-City (KR)

(72) Inventors: Junhyun PARK, Suwon-si (KR); Sunghwan KIM, Yongin-si (KR); Kyoungju SHIN, Hwaseong-si (KR); Chongchul CHAI, Seoul (KR)

(21) Appl. No.: 14/860,372

(22) Filed: Sep. 21, 2015

(30) Foreign Application Priority Data
Dec. 19, 2014 (KR) 10-2014-0184469

(51) Int. Cl. G09G 3/36; H03K 17/687

(52) U.S. Cl. CPC G09G 3/3659; G09G 3/3688; G09G 3/3696; H03K 17/6871; G09G 2300/0426; G09G 2310/0267; G09G 2310/0286; G09G 2320/0223; G09G 2330/021

(57) ABSTRACT

A display device includes a display panel and a gate driving circuit. The display panel includes a pixel-transistor and the gate driving circuit includes a driving transistor. Input and output electrodes of the pixel-transistor are symmetrically disposed with respect to a control electrode of the pixel-transistor. Input and output electrodes of the driving transistor are asymmetrically disposed with respect to a control electrode of the driving transistor. At least one of the input electrode and the output electrode is not overlapped with the control electrode.

### CROSS-REFERENCE TO RELATED APPLICATION

This U.S. non-provisional patent application claims priority under 35 U.S.C. §119 to Korean Patent Application No. 10-2014-0184469, filed on Dec. 19, 2014, the contents of which are hereby incorporated by reference in its entirety.

### BACKGROUND

1. Field of Disclosure

The present disclosure relates to a gate driving circuit and a display device having the same. More particularly, the present disclosure relates to a gate driving circuit integrated in a display panel and a display device having the gate driving circuit.

2. Description of the Related Art

A display device includes gate lines, data lines, and pixels each being connected to a corresponding gate line of the gate lines and a corresponding data line of the data lines. The display device includes a gate driving circuit to apply gate signals to the gate lines and a data driving circuit to apply data signals to the data lines.

The gate driving circuit includes a shift register including driving stage circuits (hereinafter, referred to as driving stages). Each driving stage outputs the gate signal corresponding to the gate lines. Each driving stage includes transistors connected to each other.

### SUMMARY

The present disclosure provides a gate driving circuit having improved reliability.

The present disclosure provides a display device having the gate driving circuit.

Embodiments of the inventive concept provide a gate driving circuit including a plurality of stages applying gate signals to gate lines of a display panel. Among the stages, an i-th stage (i is a natural number equal to or greater than 2) includes a Q-node, output transistors, and driving transistors.

The Q-node controls an output of a gate signal of the i-th stage or a carry signal of the i-th stage. Each of the output transistors outputs the gate signal or the carry signal of the i-th stage in accordance with a voltage level of the Q-node. The driving transistors are connected to the Q-node to control the voltage level of the Q-node.

Among the driving transistors, a first driving transistor includes a first control electrode, a first active layer, a first input electrode, and a first output electrode, and at least one of the first input electrode and the first output electrode is not overlapped with the first control electrode.

The first input electrode of the first driving transistor is disposed not to overlap with the first control electrode and the first output electrode of the first driving transistor is disposed to overlap with the first control electrode.

The first input electrode of the first driving transistor is disposed to overlap with the first control electrode and the first output electrode of the first driving transistor is disposed not to overlap with the first control electrode.

The first input electrode and the first output electrode of the first driving transistor are disposed not to overlap with the first control electrode.

The first output electrode and the first input electrode are spaced apart from each other by a predetermined distance to define a channel area, and the first driving transistor further includes an etch stopper to cover the channel area.

The first driving transistor further includes a floating electrode disposed between the first output electrode and the first input electrode and spaced apart from the first output electrode and the first input electrode.

The first driving transistor is connected between an input terminal, which is applied with the carry signal output from the (i−1)th stage, and the Q-node in a diode form to apply the carry signal output from the (i−1)th stage to the Q-node.

The first control electrode and the first input electrode of the first driving transistor are commonly receive the carry signal output from the (i−1)th stage, the first output electrode is connected to the Q-node, the first input electrode is disposed to overlap with the first control electrode, and the first output electrode is disposed not to overlap with the first control electrode.

Among the driving transistors, a second driving transistor includes a second control electrode, a second active layer, a second input electrode, and a second output electrode and applies a reference voltage applied to the second input electrode to the Q-node connected to the second output electrode in response to the carry signal output from an (i+1)th stage and applied to the second control electrode. At least one of the second input electrode and the second output electrode is not overlapped with the second control electrode.

Among the driving transistors, a third driving transistor includes a third control electrode, a third active layer, a third input electrode, and a third output electrode and applies the reference voltage applied to the third input electrode to the Q-node connected to the third output electrode in response to a switching signal generated by a clock signal applied to the third control electrode. At least one of the third input electrode and the third output electrode is not overlapped with the third control electrode.

Embodiments of the inventive concept provide a display device including a display panel and a gate driving circuit. The display panel includes a plurality of pixel rows. The gate driving circuit includes a plurality of stages connected to each other one after another.

Among the stages, an i-th stage (i is an integer number equal to or greater than 2), which applies a gate signal to an i-th pixel row, includes a first output part, a control part, a first pull-down part, a first holding part, and an inverter part.

The first output part is turned on or off in response to an electric potential of a Q-node to generate the gate signal from a clock signal, which is applied to a gate output terminal. The control part controls the electric potential of the Q-node. The first pull-down part pulls down a voltage of the gate output terminal to a first low voltage after the gate signal is output. The first holding part maintains the gate output terminal at the first low voltage after the voltage of the gate output terminal is lowered to the first low voltage. The inverter part controls an operation of the first holding part.

A pixel-transistor of the i-th pixel row includes a pixel control electrode, a pixel output electrode, and a pixel input electrode. The pixel output electrode and the pixel input electrode are symmetrically disposed with respect to the pixel control electrode.

At least one driving transistor among driving transistors connected to the Q-node includes a driving control electrode, a driving output electrode, and a driving input electrode. The driving output electrode and the driving input electrode are asymmetrically disposed with respect to the driving control electrode.

At least one of the driving input electrode and the driving output electrode is not overlapped with the driving control electrode.

The driving input electrode is disposed not to overlap with the driving control electrode and the driving output electrode is disposed to overlap with the driving control electrode.

The driving input electrode is disposed to overlap with the driving control electrode and the driving output electrode is disposed not to overlap with the driving control electrode.

The driving output electrode and the driving input electrode of the driving transistor are spaced apart from each other by a predetermined distance to define a channel area, and the driving transistor further includes an etch stopper to cover the channel area.

The driving transistor further includes a floating electrode disposed between the driving output electrode and the driving input electrode and spaced apart from the driving output electrode and the driving input electrode.

The i-th stage further includes a second output part turned on or off in response to the electric potential of the Q-node to generate the carry signal from the clock signal, which is applied to a carry output terminal.

The i-th stage further includes a second pull-down part lowering a voltage of the carry output terminal to a second low voltage after the carry signal is output.

The second low voltage has an electric potential level lower than an electric potential level of the first low voltage.

The i-th stage further comprises a second holding part maintaining the voltage of the carry output terminal at the second low voltage after the voltage of the carry output terminal is lowered to the second low voltage.

According to the above, the stress applied to the transistor, to which the high voltage is applied, is reduced by the vertical and horizontal electric fields. Thus, the reliability of the gate driving circuit and the display device is improved.

### BRIEF DESCRIPTION OF THE DRAWINGS

The above and other advantages of the present disclosure will become readily apparent by reference to the following detailed description when considered in conjunction with the accompanying drawings wherein:

FIG. 1 is a plan view showing a display device according to an exemplary embodiment of the present disclosure;

FIG. 2 is an equivalent circuit diagram showing a pixel according to an exemplary embodiment of the present disclosure;

FIG. 3 is a cross-sectional view showing a pixel according to an exemplary embodiment of the present disclosure;

FIG. 4 is a block diagram showing a gate driving circuit according to an exemplary embodiment of the present disclosure;

FIG. 5 is a circuit diagram showing an i-th driving stage among driving stages shown in FIG. 4;

FIG. 6 is a waveform diagram showing an input/output signal of the i-th driving stage shown in FIG. 5;

FIG. 7 is a layout diagram showing a portion of the stage circuit shown in FIG. 5; and

FIGS. 8, 9A, 9B, 9C and 9D are cross-sectional views showing transistors according to exemplary embodiments of the present disclosure.

### DETAILED DESCRIPTION

It will be understood that when an element or layer is referred to as being “on”, “connected to” or “coupled to” another element or layer, it can be directly on, connected or coupled to the other element or layer or intervening elements or layers may be present between the element or layer and the another element or layer. Like numbers refer to like elements throughout the specification. As used herein, the term “and/or” includes any and all combinations of one or more of the associated listed items.

It will be understood that, although the terms first, second, etc. may be used herein to describe various electrodes, transistors, and/or layers, these electrodes, transistors, and/or layers should not be limited by these terms.

The terminology used herein is for the purpose of describing particular embodiments only and is not intended to limit of the inventive concept. As used herein, the singular forms, “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present inventive concept will be explained in detail with reference to the accompanying drawings.

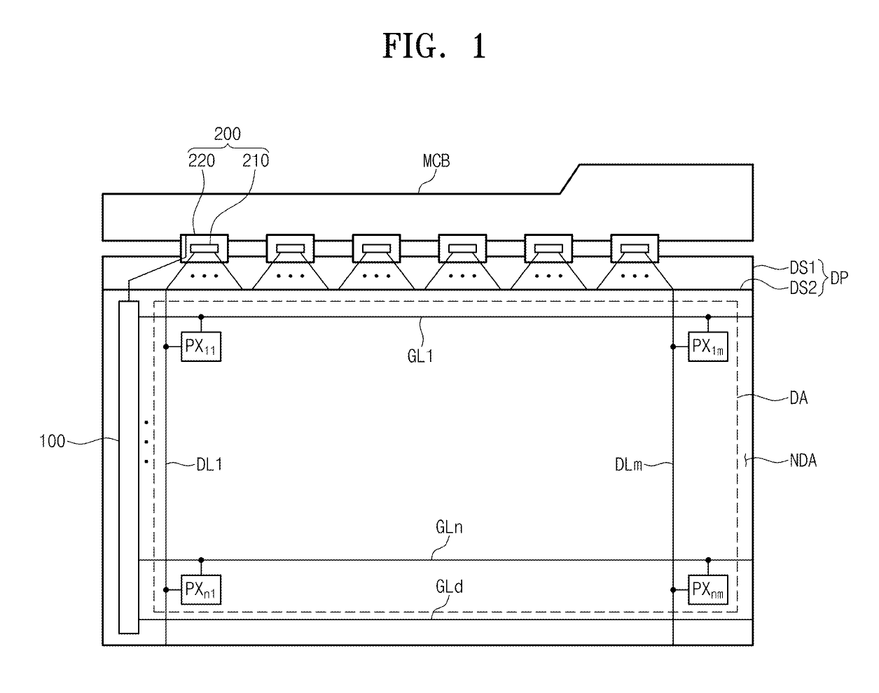

FIG. 1 is a plan view showing a display device according to an exemplary embodiment of the present disclosure.

Referring to FIG. 1, the display device includes a display panel DP, a gate driving circuit 100, and a data driving circuit 200.

The display panel DP may be various display panels, such as a liquid crystal display panel, an organic light emitting display panel, an electrophoretic display panel, an electrowetting display panel, etc. In the present exemplary embodiment, the liquid crystal display panel will be described as the display panel. The liquid crystal display panel may further include a polarizer (not shown) and a backlight unit (not shown).

The display panel DP includes a first substrate DS1, a second substrate DS2 spaced apart from the first substrate DS1, and a liquid crystal layer (not shown) interposed between the first and second substrates DS1 and DS2. The display panel DP includes a display area DA in which a plurality of pixels PX₁₁ to PXₙₘ are arranged and a non-display area NDA surrounding the display area DA when viewed in a plan view.

The display panel DP includes a plurality of gate lines GL1 to GLn disposed on the first substrate DS1 and a plurality of data lines DL1 to DLm disposed on the first substrate DS1 to cross the gate lines GL1 to GLn. The gate lines GL1 to GLn are connected to the gate driving circuit 100 and the data lines DL1 to DLm are connected to the data driving circuit 200. FIG. 1 shows a portion of the gate lines GL1 to GLn and a portion of the data lines DL1 to DLm. The display panel DP may further include a dummy gate line GLd disposed in the non-display area NDA of the first substrate DS1.

FIG. 1 shows a portion of the pixels PX₁₁ to PXₙₘ. Each of the pixels PX₁₁ to PXₙₘ is connected to a corresponding gate line of the gate lines GL1 to GLn and a corresponding data line of the data lines DL1 to DLm.

The pixels PX₁₁ to PXₙₘ are grouped into a plurality of pixel groups according to colors displayed therein. Each pixel displays one of primary colors. The primary colors include red, green, blue, and white colors, but they should not be limited thereto or thereby. That is, the primary colors may further include various colors, such as yellow, cyan, magenta, etc.

The gate driving circuit 100 may be substantially simultaneously formed together with the pixels PX₁₁ to PXₙₘ through a thin film process. For instance, the gate driving circuit 100 may be mounted on the non-display area NDA in an amorphous silicon TFT gate driver circuit (ASG) form or an oxide semiconductor TFT gate driver circuit (OSG) form.

FIG. 1 shows one gate driving circuit 100 connected to left ends of the gate lines GL1 to GLn as a representative example. In the present exemplary embodiment, the display device includes two gate driving circuits. One gate driving circuit of the two gate driving circuits may be connected to the left ends of the gate lines GL1 to GLn and the other gate driving circuit of the two gate driving circuits may be connected to right ends of the gate lines GL1 to GLn. In addition, one gate driving circuit of the two gate driving circuits may be connected to odd-numbered gate lines of the gate lines GL1 to GLn and the other gate driving circuit of the two gate driving circuits may be connected to even-numbered gate lines of the gate lines GL1 to GLn.

The data driving circuit 200 receives data signals from a timing controller (not shown) mounted on a circuit board MCB and generates analog data signals corresponding to the data signals.

The data driving circuit 200 includes a driving chip 210 and a flexible circuit board 220 on which the driving chip 210 is mounted. Each of the driving chip 210 and the flexible circuit board 220 may be provided in a plural number. The flexible circuit board 220 electrically connects the circuit board MCB and the first substrate DS1. Each of the driving chips 210 applies a corresponding data voltage of the data voltages to a corresponding data line of the data lines. Each data voltage is selected from a predetermined voltage range to correspond to a grayscale value of the data signal applied to the corresponding data line. The voltage range of each data voltage may have a value between a low voltage and a high voltage of the gate signal output from the gate driving circuit 100.

In FIG. 1, the data driving circuit 200 has a tape carrier package (TCP) form, but it should not be limited thereto or thereby. That is, the data driving circuit 200 may be mounted on the first substrate DS1 in a chip-on-glass (COG) form.

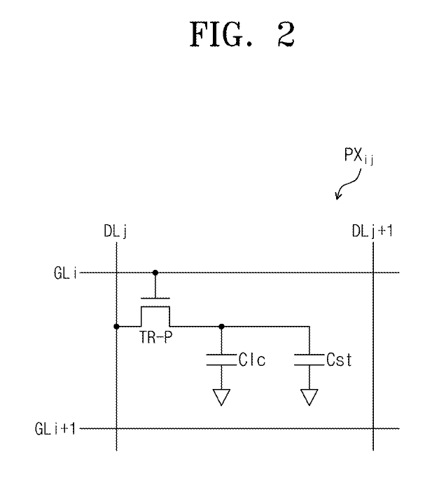

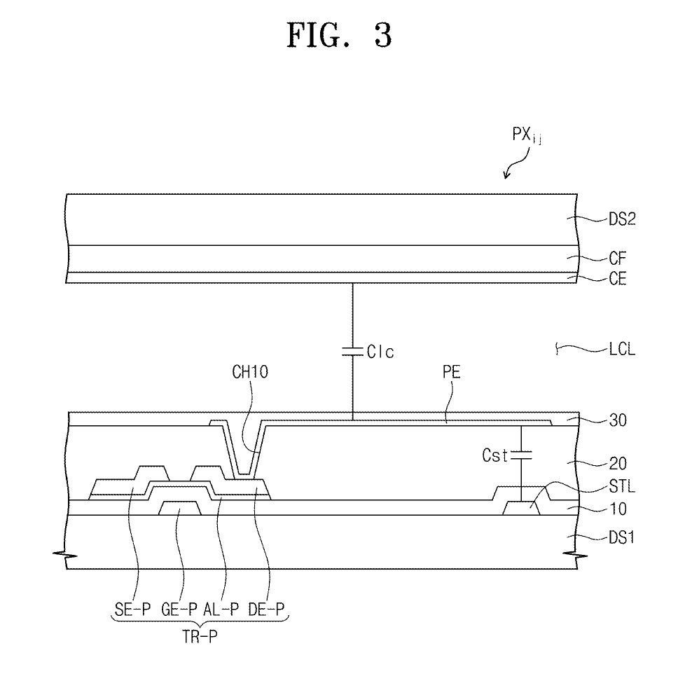

FIG. 2 is an equivalent circuit diagram showing a pixel PXᵢⱼ according to an exemplary embodiment of the present disclosure and FIG. 3 is a cross-sectional view showing a pixel according to an exemplary embodiment of the present disclosure. Each of the pixels PX₁₁ to PXₙₘ shown in FIG. 1 has the equivalent circuit shown in FIG. 2.

Referring to FIG. 2, the pixel PXᵢⱼ includes a pixel thin film transistor TR-P (hereinafter, referred to as a pixel-transistor), a liquid crystal capacitor Clc, and a storage capacitor Cst. Hereinafter, a term of “transistor” means a thin film transistor, and the storage capacitor Cst may be omitted.

The pixel-transistor TR-P is electrically connected to an i-th gate line GLi and a j-th data line DLj. The pixel-transistor TR-P outputs a pixel voltage corresponding to the data signal provided from the j-th data line DLj in response to the gate signal provided from the i-th gate line GLi.

The liquid crystal capacitor Clc is charged with the pixel voltage output from the pixel-transistor TR-P. An alignment of liquid crystal directors included in the liquid crystal layer LCL (refer to FIG. 3) is changed in accordance with an amount of electric charges accumulated in the liquid crystal capacitor Clc. Light incident on the liquid crystal layer passes through or is blocked by the alignment of the liquid crystal.

The storage capacitor Cst is connected to the liquid crystal capacitor Clc in parallel. The storage capacitor Cst maintains the alignment of the liquid crystal for a predetermined period.

Referring to FIG. 3, the pixel-transistor TR-P includes a control electrode GE-P (hereinafter, referred to as a pixel control electrode) connected to the i-th gate line GLi (refer to FIG. 2), an active layer AL-P (hereinafter, referred to as a pixel active layer) overlapped with the pixel control electrode GE-P, an input electrode SE-P (hereinafter, referred to as a pixel input electrode) connected to the j-th data line DLj (refer to FIG. 2), and an output electrode DE-P (hereinafter, referred to as a pixel output electrode) disposed to be spaced apart from the pixel input electrode SE-P.

The liquid crystal capacitor Clc includes a pixel electrode PE and a common electrode CE. The storage capacitor Cst includes the pixel electrode PE and a portion of a storage line STL overlapped with the pixel electrode PE.

The i-th gate line GLi and the storage line STL are disposed on a surface of the first substrate DS1. The pixel control electrode GE-P is branched from the i-th gate line GLi. The i-th gate line GLi and the storage line STL includes a metal material, such as aluminum (Al), silver (Ag), copper (Cu), molybdenum (Mo), chromium (Cr), tantalum (Ta), titanium (Ti), or an alloy thereof. Each of the i-th gate line GLi and the storage line STL may have a multi-layer structure of an titanium layer and a copper layer.

A first insulating layer 10 is disposed on the first substrate DS1 to cover the pixel control electrode GE-P and the storage line STL. The first insulating layer 10 includes at least one of an inorganic material and an organic material. The first insulating layer 10 is an organic or inorganic layer. The first insulating layer 10 may have a multi-layer structure of a silicon nitride layer and a silicon oxide layer.

The pixel active layer AL-P is disposed on the first insulating layer 10 to overlap with the pixel control electrode GE-P. The pixel active layer AL-P includes a semiconductor layer and an ohmic contact layer (not shown).

The pixel active layer AL-P includes amorphous silicon or polysilicon. In addition, the pixel active layer AL-P may include a metal oxide semiconductor.

The pixel output electrode DE-P and the pixel input electrode SE-P are disposed on the pixel active layer AL-P. The pixel output electrode DE-P and the pixel input electrode SE-P are spaced apart from each other. Each of the pixel output electrode DE-P and the pixel input electrode SE-P is partially overlapped with the pixel control electrode GE-P.

FIG. 3 shows the pixel-transistor TR-P having a staggered structure, but the structure of the pixel-transistor TR-P should not be limited to the staggered structure. That is, the pixel-transistor TR-P may have a planar structure.

A second insulating layer 20 is disposed on the first insulating layer 10 to cover the pixel active layer AL-P, the pixel output electrode DE-P, and the pixel input electrode SE-P. The second insulating layer 20 provides a planar surface. The second insulating layer 20 includes an organic material.

The pixel electrode PE is disposed on the second insulating layer 20. The pixel electrode PE is connected to the pixel output electrode DE-P through a contact hole CH10 formed through the second insulating layer 20. An alignment layer 30 is disposed on the second insulating layer 20 to cover the pixel electrode PE.

A color filter layer CF is disposed on a surface of the second substrate DS2. The common electrode CE is disposed on the color filter layer CF. The common electrode CE is applied with a common voltage. The common voltage has a level different from that of the pixel voltage. An alignment layer (not shown) may be disposed on the common electrode CE to cover the common electrode. Another insulating layer (not shown) may be disposed between the color filter layer CF and the common electrode CE.

The pixel electrode PE and the common electrode CE, which face each other such that the liquid crystal layer LCL is disposed between the pixel electrode PE and the common electrode CE, form the liquid crystal capacitor Clc. In addition, the pixel electrode PE and the portion of the storage line STL, which face each other such that the first and second insulating layers 10 and 20 are disposed between the pixel electrode PE and the portion of the storage line STL, form the storage capacitor Cst. The storage line STL is applied with a storage voltage having a level different from that of the pixel voltage. The storage voltage may have the same level as that of the common voltage.

Meanwhile, different from the structure of the pixel PXᵢⱼ, at least one of the color filter layer CF and the common electrode CE may be disposed on the first substrate DS1. In other words, the liquid crystal display panel according to the present exemplary embodiment may include a vertical alignment (VA) mode pixel, a patterned vertical alignment (PVA) mode pixel, an in-plane switching (IPS) mode pixel, a fringe-field switching (FFS) mode pixel, or a plane-to-line switching (PLS) mode pixel.

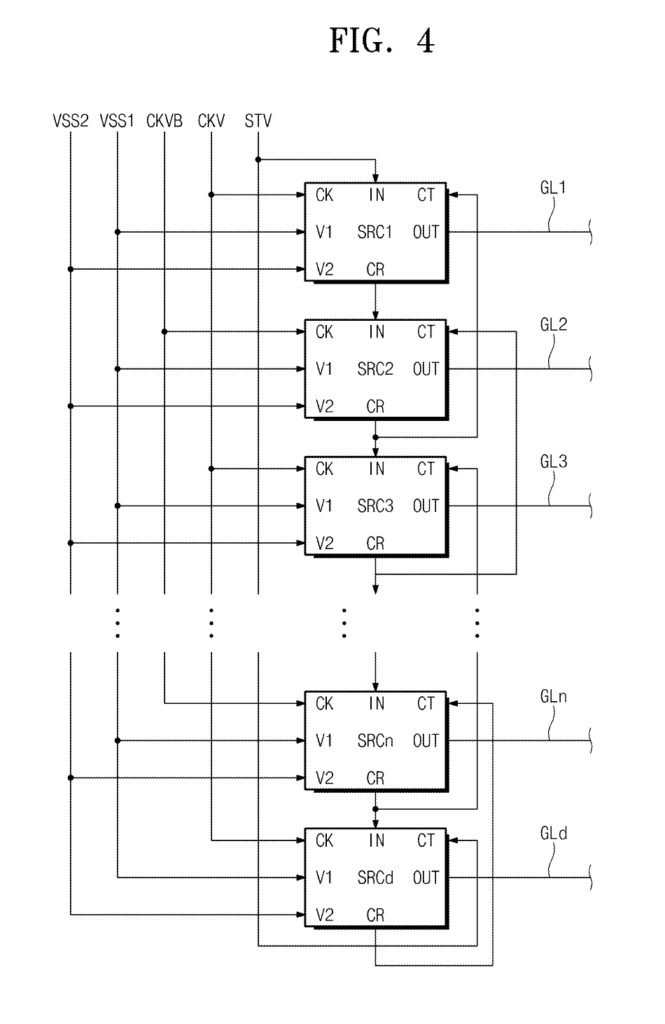

FIG. 4 is a block diagram showing the gate driving circuit 100 according to an exemplary embodiment of the present disclosure.

Referring to FIG. 4, the gate driving circuit 100 includes a plurality of driving stages SRC1 to SRCn connected to each other one after another.

The driving stages SRC1 to SRCn are respectively connected to the gate lines GL1 to GLn. The driving stages SRC1 to SRCn apply the gate signals to the gate lines GL1 to GLn, respectively. In the present exemplary embodiment, the gate lines connected to the driving stages SRC1 to SRCn may be the odd-numbered gate lines or the even-numbered gate lines among the gate lines GL1 to GLn.

The gate driving circuit 100 may further include a dummy stage SRCd connected to a last driving stage SRCn among the driving stages SRC1 to SRCn. The dummy stage SRCd is connected to the dummy gate line GLd.

Each of the driving stages SRC1 to SRCn includes an output terminal OUT, a carry terminal CR, an input terminal IN, a control terminal CT, a clock terminal CK, a first voltage input terminal V1, and a second voltage input terminal V2.

The output terminal OUT of each of the driving stages SRC1 to SRCn is connected to a corresponding gate line of the gate lines GL1 to GLn. The gate signals generated by the driving stages SRC1 to SRCn are applied to the gate lines GL1 to GLn through the output terminals OUT.

The carry terminal CR of each of the driving stages SRC1 to SRCn is electrically connected to the input terminal IN of a next driving stage following the corresponding driving stage. The carry terminal CR of each of the driving stages SRC1 to SRCn outputs a carry signal.

The input terminal IN of each of the driving stages SRC1 to SRCn receives the carry signal from a previous driving stage prior to the corresponding driving stage. For instance, the input terminal IN of a third driving stage SRC3 receives the carry signal output from a second driving stage SRC2. Among the driving stages SRC1 to SRCn, the input terminal IN of a first driving stage SRC1 receives a start signal STV that starts an operation of the gate driving circuit 100 instead of the carry signal output from the previous driving stage.

The control terminal CT of each of the driving stages SRC1 to SRCn is electrically connected to the carry terminal CR of the next driving stage following the corresponding driving stage. The control terminal CT of each of the driving stages SRC1 to SRCn receives the carry signal output from the next driving stage following the corresponding driving stage. For instance, the control terminal CT of the second driving stage SRC2 receives the carry signal output from the carry terminal CR of the third driving stage SRC3. In the present exemplary embodiment, the control terminal CT of each of the driving stages SRC1 to SRCn may be electrically connected to the output terminal OUT of the next driving stage following the corresponding driving stage.

The control terminal CT of the last driving stage SRCn receives the carry signal output from the carry terminal CR of the dummy stage SRCd. The control terminal CT of the dummy stage SRCd receives the start signal STV.

The clock terminal CK of each of the driving stages SRC1 to SRCn receives a first clock signal CKV or a second clock signal CKVB. The clock terminals CK of the odd-numbered driving stages SRC1 and SRC3 among the driving stages SRC1 to SRCn receive the first clock signal CKV. The clock terminals CK of the even-numbered driving stages SRC2 and SRCn among the driving stages SRC1 to SRCn receive the second clock signal CKVB. The first and second clock signals CKV and CKVB have different phases from each other.

The first voltage input terminal V1 of each of the driving stages SRC1 to SRCn receives a first low voltage VSS1 and the second voltage input terminal V2 of each of the driving stages SRC1 to SRCn receives a second low voltage VSS2. The second low voltage VSS2 has a level lower than that of the first low voltage VSS1.

In each of the driving stages SRC1 to SRCn according to the present exemplary embodiment, one of the output terminal OUT, the input terminal IN, the carry terminal CR, the control terminal CT, the clock terminal CK, the first voltage input terminal V1, and the second voltage input terminal V2 may be omitted or another terminal may be added to each of the driving stages SRC1 to SRCn. For instance, one of the first and second voltage input terminals V1 and V2 may be omitted. In addition, a connection relation between the driving stages SRC1 to SRCn may be changed.

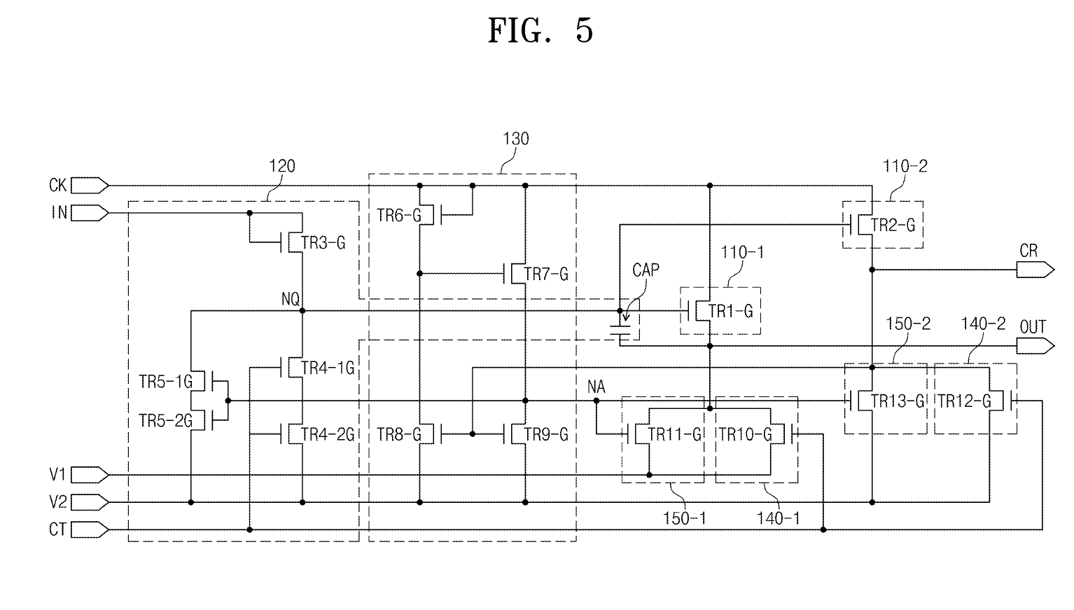

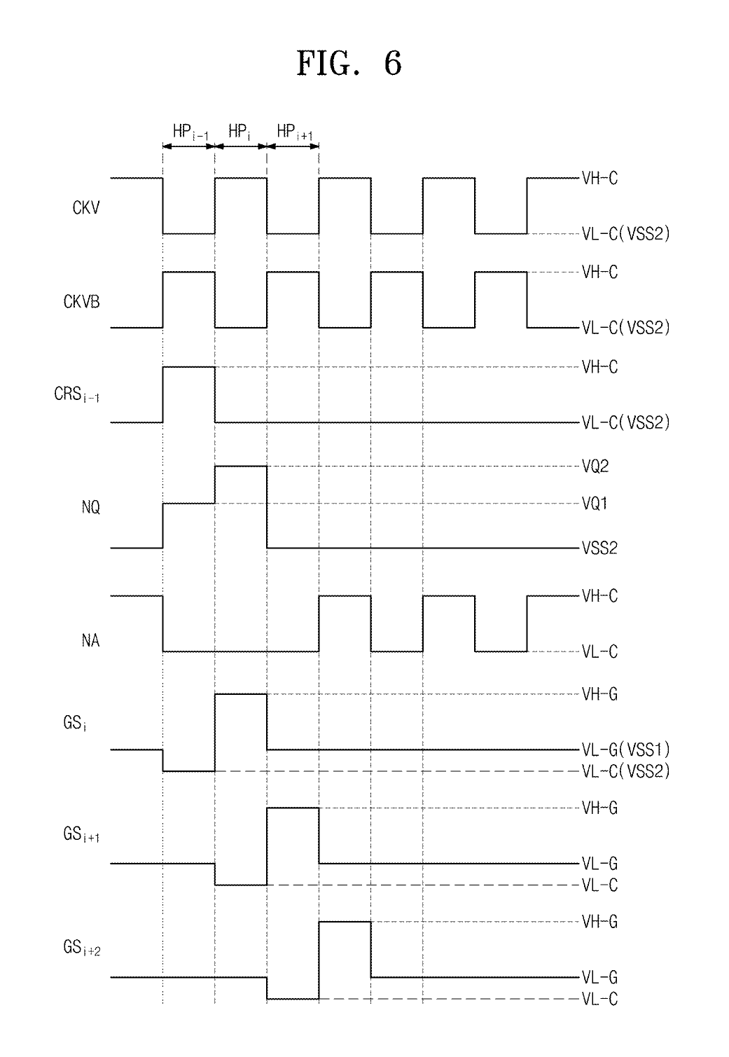

FIG. 5 is a circuit diagram showing an i-th driving stage among the driving stages shown in FIG. 4 and FIG. 6 is a waveform diagram showing an input/output signal of the i-th driving stage shown in FIG. 5.

FIG. 5 shows the i-th driving stage SRCi among the driving stages SRC1 to SRCn shown in FIG. 4. Each of the driving stages SRC1 to SRCn shown in FIG. 4 may have the same circuit configuration as that of the i-th driving stage SRCi.

Referring to FIGS. 5 and 6, the i-th driving stage SRCi includes output parts 110-1 and 110-2, a control part 120, an inverter part 130, pull-down parts 140-1 and 140-2, and holding parts 150-1 and 150-2. The output parts 110-1 and 110-2 include a first output part 110-1 outputting an i-th gate signal GSi and a second output part 110-2 outputting an i-th carry signal CRSi. The pull-down parts 140-1 and 140-2 include a first pull-down part 140-1 lowering the output terminal OUT and a second output part 140-2 lowering the carry terminal CR. The holding parts 150-1 and 150-2 include a first holding part 150-1 allowing the output terminal OUT to maintain the lowered state and a second holding part 150-2 allowing the carry terminal CR to maintain the lowered state.

The circuit configuration of the i-th driving stage SRCi should not be limited to the above-mentioned configuration.

The first output part 110-1 includes a first output transistor TR1-G. The first output transistor TR1-G includes an input electrode applied with the first clock signal CKV, a control electrode connected to an Q-node NQ, and an output electrode outputting the i-th gate signal GSi. The first output transistor TR1-G controls an output of the gate signal in accordance with a voltage level of the Q-node NQ. The Q-node NQ controls an output of a gate signal or a carry signal. The second output part 110-2 includes a second output transistor TR2-G. The second output transistor TR2-G includes an input electrode applied with the first clock signal CKV, a control electrode connected to the Q-node NQ, and an output electrode outputting the i-th carry signal CRSi. The second output transistor TR2-G controls an output of the carry signal in accordance with a voltage level of the Q-node NQ.

As shown in FIG. 6, the first and second clock signals CKV and CKVB have opposite phases to each other. The first and second clock signals CKV and CKVB have a phase difference of about 180 degrees. Each of the first and second clock signals CKV and CKVB includes low periods VL-C (hereinafter, referred to as a low voltage) having a relatively low level and high period VH-C (hereinafter, referred to as a high voltage) having a relatively high level. The low periods are alternately arranged with the high periods in each of the first and second clock signals CKV and CKVB. The high voltage VH-C is about 10 volts and the low voltage VL-C is about −16 volts. The low voltage VL-C may have the same level as that of the second low voltage VSS2 (refer to FIG. 5).

The i-th gate signal GSi includes a low period VL-G (hereinafter, referred to as a low voltage) having a relatively low level and a high period VH-G (hereinafter, referred to as a high voltage) having a relatively high level. The low voltage VL-G of the i-th gate signal GSi may have the same level as that of the first low voltage VSS1 (refer to FIG. 5). The low voltage VL-G is about −13 volts.

The i-th gate signal GSi may have the same level as that of the low voltage VL-C of the first clock signal CKV or the second clock signal CKVB during periods. The low voltage VL-C of the first clock signal CKV or the second clock signal CKVB is output by the Q-node NQ that is pre-charged before the i-th gate signal GSi rises to the high voltage VH-G.

The high voltage VH-G of the i-th gate signal GSi has the same level as that of the first clock signal CKV or the second clock signal CKVB.

The i-th carry signal CRSi includes a low period VL-C (hereinafter, referred to as a low voltage) having the relatively low voltage and a high period VH-C (hereinafter, referred to as a high voltage) having the relatively high voltage. Since the i-th carry signal CRSi is generated on the basis of the first clock signal CKV, the i-th carry signal CRSi has the same or similar voltage level as that of the first clock signal CKV.

Referring to FIGS. 5 and 6, the control part 120 controls an operation of the first and second output parts 110-1 and 110-2. The control part 120 turns on the first and second output parts 110-1 and 110-2 in response to an (i−1)th carry signal CRSᵢ₋₁ output from an (i−1)th driving stage SRCᵢ₋₁. The control part 120 turns off the first and second output parts 110-1 and 110-2 in response to an (i+1)th carry signal CRSᵢ₊₁ output from an (i+1)th driving stage SRCᵢ₊₁. The control part 120 controls the first and second output parts 110-1 and 110-2 in response to a switching signal output from the inverter part 130 such that the first and second output parts 110-1 and 110-2 are maintained in the turned-off state.

The control part 120 includes a first control transistor TR3-G, second control transistors TR4-1G and TR4-2G, third control transistors TR5-1G and TR5-2G, and a capacitor CAP. In the present exemplary embodiment, two second control transistors TR4-1G and TR4-2G connected to each other in series and two third control transistors TR5-1G and TR5-2G connected to each other in series are shown.

The first control transistor TR3-G applies a control signal to the Q-node NQ to control an electric potential of the Q-node NQ.

FIG. 6 shows a horizontal period HPᵢ, (hereinafter, referred to as an i-th horizontal period), in which the i-th gate signal GSi is output, a previous horizontal period HPᵢ₋₁ (hereinafter, referred to as an (i−1)th horizontal period), and a next horizontal period HPᵢ₋₁ (hereinafter, referred to as an (i+1)th horizontal period).

The first control transistor TR3-G is connected between the input terminal IN and the Q-node NQ in a diode form such that a current path is formed between the input terminal IN and the Q-node NQ. The first control transistor TR3-G includes a control electrode and an input electrode, which are commonly connected to the input terminal IN, and an output electrode connected to the Q-node NQ.

The capacitor CAP is connected between the output electrode of the first output transistor TR1-G and the control electrode (or the Q-node NQ) of the first output transistor TR1-G.

The two second control transistors TR4-1G and TR4-2G are connected between the second voltage input terminal V2 and the Q-node NQ in series. Control electrodes of the two second control transistors TR4-1G and TR4-2G are commonly connected to the control terminal CT. The two second control transistors TR4-1G and TR4-2G apply the second low voltage VSS2 to the Q-node NQ in response to the (i+1)th carry signal (not shown) output from the (i+1)th stage. In the present exemplary embodiment, the two second control transistors TR4-1G and TR4-2G may be turned on by the (i+1) the gate signal GSᵢ₊₁.

The two third control transistors TR5-1G and TR5-2G are connected between the second voltage input terminal V2 and the Q-node NQ in series. Control electrodes of the two third control transistors TR5-1G and TR5-2G are commonly connected to an A-node NA. The two third control transistors TR5-1G and TR5-2G apply the second low voltage VSS2 to the Q-node NQ in response to the switching signal output from the inverter part 130.

In the present exemplary embodiment, one of the two second control transistors TR4-1G and TR4-2G may be omitted and one of the two third control transistors TR5-1G and TR5-2G may be omitted. In addition, the second control transistors TR4-1G and TR4-2G or the third control transistors TR5-1G and TR5-2G may be connected to the first voltage input terminal V1 rather than the second voltage input terminal V2.

As shown in FIG. 6, the electric potential of the Q-node NQ rises to a first high voltage VQ1 by the (i−1)th carry signal CRSᵢ₋₁ during the (i−1)th horizontal period HPᵢ₋₁. When the (i−1)th carry signal CRSᵢ₋₁ is applied to the Q-node NQ, the capacitor CAP is charged with a voltage corresponding to the (i−1)th carry signal CRSᵢ₋₁. The i-th gate signal GSᵢ is output during the i-th horizontal period HPᵢ. In this case, the Q-node NQ is boosted to a second high voltage VQ2 from the first high voltage VQ1.

The voltage of the Q-node NQ is lowered to the second low voltage VSS2 during the (i+1)th horizontal period HPᵢ₊₁. Accordingly, the first and second output transistors TR1-G and TR1-2G are turned off. The voltage of the Q-node NQ is maintained at the second low voltage VSS2 until the i-th gate signal GSᵢ of the next frame period is output. Therefore, the first and second output transistors TR1-G and TR2-G are maintained in the turned-off state until the i-th gate signal GSᵢ of the next frame period is output.

Referring to FIGS. 5 and 6, the inverter part 130 applies the switching signal to the A-node NA. The inverter part 130 includes first, second, third, and fourth inverter transistors TR6-G, TR7-G, TR8-G, and TR9-G. The first inverter transistor TR6-G includes an input electrode and a control electrode, which are commonly connected to the clock terminal CK, and an output electrode connected to a control electrode of the second inverter transistor TR7-G. The second inverter transistor TR7-G includes an input electrode connected to the clock terminal CK, an output electrode connected to the A-node NA, and the control electrode connected to the output electrode of the first inverter transistor TR6-G.

The third inverter transistor TR8-G includes an output electrode connected to the output electrode of the first inverter transistor TR6-G, a control electrode connected to the carry terminal CR, and an input electrode connected to the second voltage input terminal V2. The fourth inverter transistor TR9-G includes an output electrode connected to the A-node NA, a control electrode connected to the carry terminal CR, and an input electrode connected to the second voltage input terminal V2. In the present exemplary embodiment, the control electrodes of the third and fourth inverter transistors TR8-G and TR9-G may be connected to the output terminal OUT and the input electrodes of the third and fourth inverter transistors TR8-G and TR9-G may be connected to the first voltage input terminal V1.

As shown in FIG. 6, the A-node NA has substantially the same phase as that of the first clock signal CKV except for the i-th horizontal period HPᵢ. During the i-th horizontal period HPᵢ, the third and fourth inverter transistors TR8-G and TR9-G are turned on in response to the i-th carry signal CRSᵢ. In this case, the high voltage VH-C of the first clock signal CKV output from the second inverter transistor TR7-G is discharged to the second low voltage VSS2. During the periods except for the i-th horizontal period HPᵢ, the high voltage VH-C and the low voltage VL-C of the first clock signal CKV, which are output from the second inverter transistor TR7-G, are applied to the A-node NA. The high voltage VH-C and the low voltage VL-C of the first clock signal CKV, which are alternated with each other, are applied to the other transistors as the switching signals.

The first pull-down part 140-1 includes a first pull-down transistor TR10-G. The first pull-down transistor TR10-G includes an input electrode connected to the first voltage input terminal V1, a control electrode connected to the control terminal CT, and an output electrode connected to the output electrode of the first output transistor TR1-G. In the present exemplary embodiment, the input electrode of the first pull-down transistor TR10-G may be connected to the second voltage input terminal V2.

As shown in FIG. 6, the voltage of the i-th gate signal GSᵢ, after the (i+1)th horizontal period HPᵢ₊₁ corresponds to the voltage of the output electrode of the first output transistor TR1-G. During the (i+1)th horizontal period HPᵢ₊₁, the first pull-down transistor TR10-G applies the first low voltage VSS1 to the output electrode of the first output transistor TR1-G in response to the (i+1)th carry signal.

The second pull-down part 140-2 includes a second pull-down transistor TR12-G. The second pull-down transistor TR12-G includes an input electrode connected to the second voltage input terminal V2, a control electrode connected to the control terminal CT, and an output electrode connected to the output electrode of the second output transistor TR2-G In the present exemplary embodiment, the input electrode of the second pull-down transistor TR12-G may be connected to the first voltage input terminal V1.

As shown in FIG. 6, the voltage of the i-th carry signal CRSᵢ after the (i+1)th horizontal period HPᵢ₊₁ corresponds to the voltage of the output electrode of the second output transistor TR2-G. During the (i+1)th horizontal period HPᵢ₊₁, the second pull-down transistor TR12-G applies the second low voltage VSS2 to the output electrode of the second output transistor TR2-G in response to the (i+1)th carry signal.

The first holding part 150-1 includes a first holding transistor TR11-G. The first holding transistor TR11-G includes an input electrode connected to the first voltage input terminal V1, a control electrode connected to the A-node NA, and an output electrode connected to the output electrode of the first output transistor TR1-G. In the present exemplary embodiment, the input electrode of the first holding transistor TR11-G may be connected to the second voltage input terminal V2.

As shown in FIG. 6, the first holding transistor TR11-G applies the first low voltage VSS1 to the output electrode of the first output transistor TR1-G in response to the switching signal output from the A-node NA after the (i+1)th horizontal period HPᵢ₊₁.

The second holding part 150-2 includes a second holding transistor TR13-G The second holding transistor TR13-G includes an input electrode connected to the second voltage input terminal V2, a control electrode connected to the A-node NA, and an output electrode connected to the output electrode of the second output transistor TR2-G In the present exemplary embodiment, the input electrode of the second holding transistor TR13-G may be connected to the first voltage input terminal V1.

As shown in FIG. 6, the second holding transistor TR13-G applies the second low voltage VSS2 to the output electrode of the second output transistor TR2-G in response to the switching signal output from the A-node NA after the (i+1)th horizontal period HPᵢ₊₁.

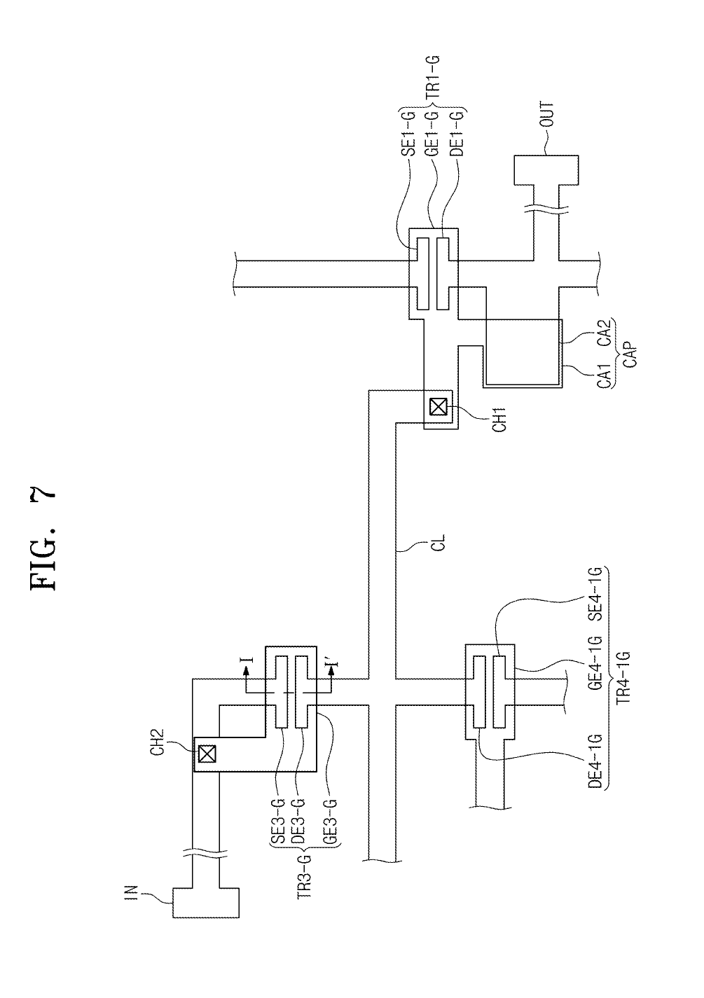

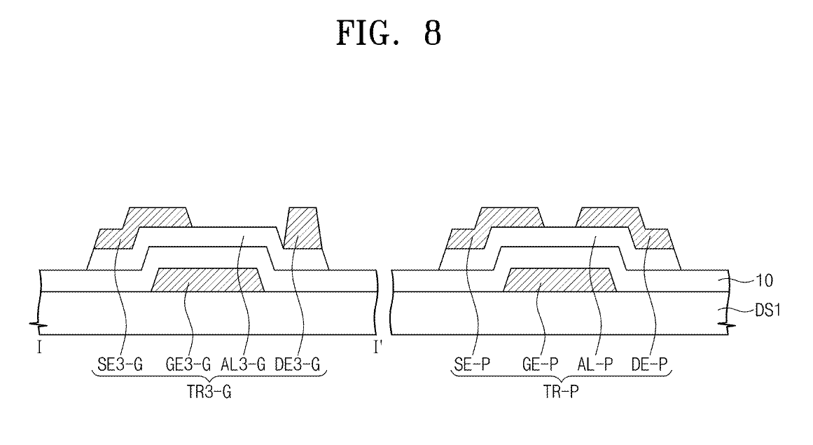

FIG. 7 is a layout diagram showing a portion of the stage circuit shown in FIG. 5 and FIG. 8 is a cross-sectional view showing a cross section taken along a line I-I′ of FIG. 7 and a cross section of the pixel-transistor show in FIG. 3.

FIG. 7 shows a connection structure between the first output transistor TR1-G of the i-th driving stage SRCᵢ (refer to FIG. 5), the first control transistor TR3-G, and the second control transistor TR4-1G As described later, the first output transistor TR1-G of the i-th driving stage SRCᵢ, the first control transistor TR3-G, and the second control transistor TR4-1G have the same structure.

In detail, the i-th driving stage SRCi includes a first conductive layer and a second conductive layer, which are disposed on different layers from each other. The first and second conductive layers include a plurality of electrodes and a plurality of lines, which are patterned. An insulating layer is disposed between the first and second conductive layers.

As shown in FIGS. 7 and 8, portions of the first conductive layer form the control electrodes GE1-G, GE3-G, and GE4-1G of the transistors TR1-G, TR3-G, and TR4-1G. Portions of the second conductive layer form the input electrodes SE1-G, SE3-G, and SE4-1G and the output electrodes DE1-G, DE3-G, and DE4-1G of the transistors TR1-G, TR3-G, and TR4-1G.

The second conductive layer includes a connection line CL to connect the transistors TR1-G, TR3-G, and TR4-1G to each other. The connection line CL corresponds to the Q-node NQ shown in FIG. 5.

The control electrode GE1-G of the first output transistor TR1-G is connected to the connection line CL through a first contact hole CH1 formed through the insulating layer disposed between the first and second conductive layers. The control electrode GE1-G of the first output transistor TR1-G is connected to the first electrode CA1 of the capacitor CAP. The output electrode DE1-G of the first output transistor TR1-G is connected to the second electrode CA2 of the capacitor CAP.

The control electrode GE3-G of the first control transistor TR3-G is connected to the input electrode SE3-G of the first control transistor TR3-G and the input terminal IN through a second contact hole CH2 formed through the insulating layer disposed between the first and second conductive layers.

As shown in FIG. 8, the control electrode GE3-G of the first control transistor TR3-G is disposed on the same layer as the pixel control electrode GE-P of the pixel-transistor TR-P. The control electrode GE3-G of the first control transistor TR3-G includes the same material and the same layer structure as those of the pixel control electrode GE-P of the pixel-transistor TR-P.

The input electrode SE3-G and the output electrode DE3-G of the first control transistor TR3-G are disposed on the same layer as the pixel input electrode SE-P and the pixel output electrode DE-P of the pixel-transistor TR-P. The input electrode SE3-G and the output electrode DE3-G of the first control transistor TR3-G include the same material and the same layer structure as those of the pixel input electrode SE-P and the pixel output electrode DE-P of the pixel-transistor TR-P.

The first insulating layer 10 is commonly disposed on the same layer of the first control transistor TR3-G and the pixel transistor TR-P.

An active layer AL3-G of the first transistor TR3-G is disposed on the same layer as the active layer AL-P of the pixel-transistor TR-P. The active layer AL3-G of the first transistor TR3-G includes the same material and the same layer structure as those of the active layer AL-P of the pixel-transistor TR-P.

The layer structure of the pixel-transistor TR-P is the same as shown in FIG. 3. In addition, the layer structure of the first control transistor TR3-G is substantially the same as the layer structure of the pixel-transistor TR-P.

Hereinafter, the input electrode SE3-G, the output electrode DE3-G, and the control electrode GE3-G of the first control transistor TR3-G will be mainly described in detail. The input electrode SE3-G and the output electrode DE3-G of the first transistor TR3-G are disposed on the active layer AL3-G and spaced apart from each other.

The input electrode SE3-G of the first control transistor TR3-G is partially overlapped with the control electrode GE3-G of the first control transistor TR3-G However, the output electrode DE3-G of the first control transistor TR3-G is not overlapped with the control electrode GE3-G of the first control transistor TR3-G.

Accordingly, the input electrode SE3-G and the output electrode DE3-G of the first control transistor TR3-G are asymmetrically disposed with respect to the control electrode GE3-G However, the pixel input electrode SE-P and the pixel output electrode DE-P of the pixel-transistor TR-P are symmetrically disposed with respect to the pixel control electrode GE-P.

The Q-node NQ (refer to FIGS. 5 and 6) is applied with a high voltage corresponding to a difference between the second high voltage VQ2 and the second low voltage VSS2 during the i-th horizontal period HPᵢ. Thus, different from the other horizontal periods the output electrode DE3-G of the first control transistor TR3-G is applied with the second high voltage VQ2 during the i-th horizontal period HPᵢ, and the input electrode SE3-G of the first control transistor TR3-G is applied with the second low voltage VSS2 during the i-th horizontal period HPᵢ. This means that the first control transistor TR3-G, which serves as the diode, is applied with a reverse bias voltage having the high voltage.

For instance, when the second high voltage VQ2 is about 35 volts and the second low voltage VSS2 is about −10 volts, the reverse bias voltage having the high voltage of about 45 volts is applied to the first control transistor TR3-G Accordingly, the first control transistor TR3-G receives a stress caused by the reverse bias voltage having the high voltage. Similarly, the other transistors connected to the Q-node NQ (refer to FIGS. 5 and 6) receive the same stress as the first control transistor TR3-G.

When the transistors connected to the Q-node NQ (refer to FIGS. 5 and 6) are burned and deteriorated due to the continuous stress caused by the high voltage, current characteristics of the transistors are degraded. Therefore, the Q-node NQ (refer to FIGS. 5 and 6) is not properly charged, and thus the electric potential level of the Q-node (refer to FIGS. 5 and 6) does not rise to the required level.

As shown in FIG. 8, when the output electrode DE3-G of the first control transistor TR3-G is not overlapped with the control electrode GE3-G of the first control transistor TR3-G, an intensity of a vertical electric field generated between the output electrode DE3-G and the control electrode GE3-G becomes weak. In addition, a distance between the output electrode DE3-G of the first control transistor TR3-G and the input electrode SE3-G of the first control transistor TR3-G becomes great, an intensity of a horizontal electric field generated between the output electrode DE3-G and the input electrode SE3-G becomes weak. As described above, when the intensity of the vertical and horizontal electric fields generated between the electrodes of the first control transistor TR3-G becomes weak, the stress caused by the high voltage applied to the first control transistor TR3-G is reduced. Accordingly, the transistors are prevented from burning and deteriorating due to the high voltage, and thus reliability of the gate driving circuit is improved.

On the other hand, the stress applied to the pixel-transistor TR-P is relatively smaller than that applied to the first control transistor TR3-G This is because the voltage applied to the pixel-transistor TR-P is determined depending on a voltage level of the signal output from the gate driving circuit 100 (refer to FIG. 1) and a voltage level of the signal output from the data driving circuit 200 (refer to FIG. 1). For instance, when the voltage level of the signal output from the gate driving circuit 100 (refer to FIG. 1) is about 14 volts and the voltage level of the signal output from the data driving circuit 200 (refer to FIG. 1) is about 8 volts, a maximum voltage applied to the pixel-transistor TR-P is about 15 volts, which is extremely smaller than a maximum voltage of about 45 volts, which is applied to the Q-node NQ (refer to FIGS. 5 and 6).

Therefore, the pixel-transistor TR-P is substantially not deteriorated, and thus reliability of the display panel DP is improved even though the pixel-transistor TR-P has the structure that the pixel input electrode SE-P or the pixel output electrode DE-P is overlapped with the pixel control electrode GE-P, which is different from that of the first control transistor TR3-G.

As shown in FIG. 8, the first control transistor TR3-G and the pixel-transistor TR-P have the same layer structure. Thus, the first control transistor TR3-G and the pixel-transistor TR-P may be formed without using an additional mask. Due to the arrangement of the input electrode SE3-G, the output electrode DE3-G, and the control electrode GE3-G of the first control transistor TR3-G, the gate driving circuit may have improved reliability without influencing on the manufacturing process.

The structure that the output electrode is not overlapped with the control electrode and the input electrode is overlapped with the control electrode should not be limited to the first control transistor TR3-G since the transistors connected to the Q-node NQ (refer to FIGS. 5 and 6) may be applied with the stress caused by the high voltage applied to the Q-node NQ (refer to FIGS. 5 and 6). Therefore, the structure applied to the first control transistor TR3-G may be applied to all the transistors connected to the Q-node NQ (refer to FIGS. 5 and 6).

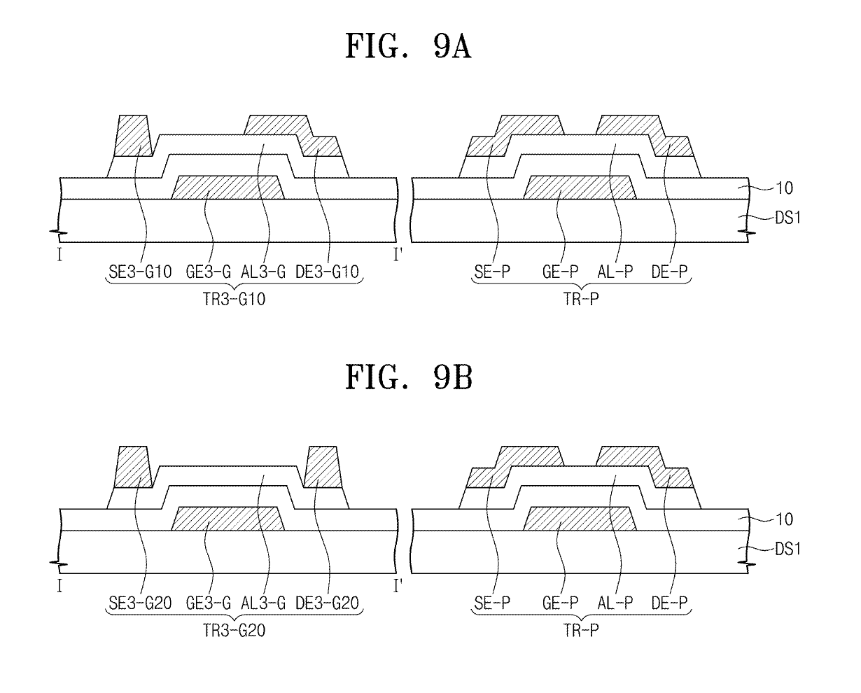

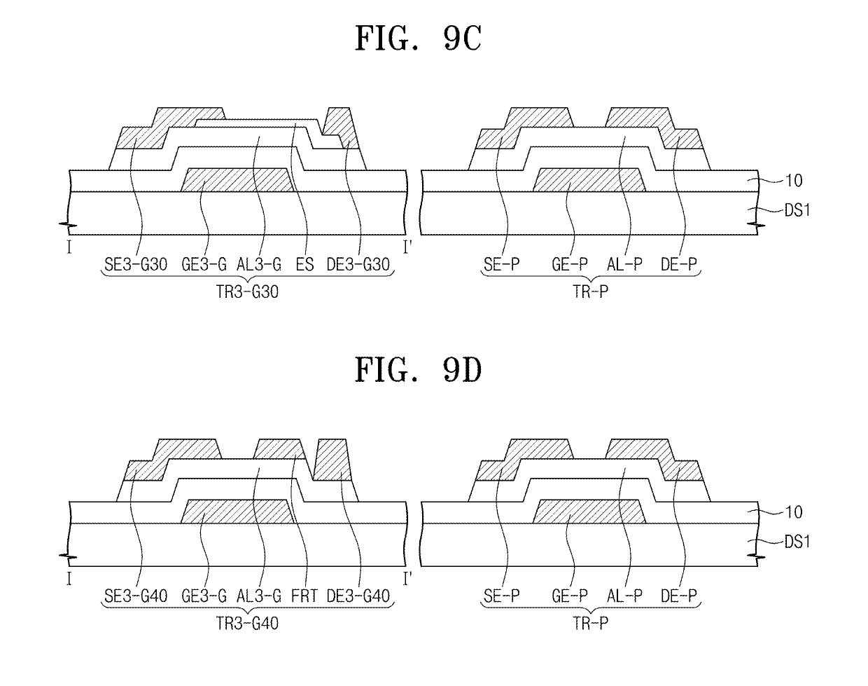

FIGS. 9A to 9D are cross-sectional views showing transistors according to exemplary embodiments of the present disclosure.

Referring to FIG. 9A, an output electrode DE3-G10 of a first control transistor TR3-G10 is disposed to partially overlap with a control electrode GE3-G of a first control transistor TR3-G10. On the other hand, an input electrode SE3-G10 of the first control transistor TR3-G10 is not overlapped with the control electrode GE3-G of the first control transistor TR3-G10. This structure shown in FIG. 9A corresponds to a structure obtained by left-and-right reversing the input electrode SE3-G and the output electrode DE3-G of the first control transistor TR3-G.

Accordingly, the input electrode SE3-G10 and the output electrode DE3-G10 of the first control transistor TR3-G10 are asymmetrically disposed with respect to the control electrode GE3-G On the other hand, the pixel input electrode SE-P and the pixel output electrode DE-P of the pixel-transistor TR-P are symmetrically disposed with respect to the pixel control electrode GE-P.

The effects according to the arrangement shown in FIG. 9A and efficiencies of the processes according to the structure shown in FIG. 9A are the same as those described with reference to FIG. 8.

The structure that the input electrode is not overlapped with the control electrode and the output electrode is overlapped with the control electrode should not be limited to the first control transistor TR3-G10 since transistors connected to the Q-node NQ (refer to FIGS. 5 and 6) may be applied with the stress caused by the high voltage applied to the Q-node NQ (refer to FIGS. 5 and 6). Therefore, the structure applied to the first control transistor TR3-G10 may be applied to all the transistors connected to the Q-node NQ (refer to FIGS. 5 and 6).

Referring to FIG. 9B, an input electrode SE3-G20 and an output electrode DE3-G20 of a first control transistor TR3-G20 are not overlapped with a control electrode GE3-G of the first control transistor TR3-G20.

Accordingly, the input electrode SE3-G20 and the output electrode DE3-G20 of the first control transistor TR3-G20 are symmetrically disposed with respect to the control electrode GE3-G.

As described above, when the input electrode SE3-G20 and the output electrode DE3-G20 of the first control transistor TR3-G20 are not overlapped with the control electrode GE3-G, a mobility of electrons and holes may be lowered in a channel area of the first control transistor TR3-G20. This may be compensated by optimizing an effective channel length or a channel width of the first control transistor TR3-G20.

The effects according to the arrangement of the input electrode SE3-G20, the output electrode DE3-G20, and the control electrode GE3-G of the first control transistor TR3-G20 shown in FIG. 9B and efficiencies of the processes according to the structure shown in FIG. 9B are the same as those described with reference to FIG. 8.

The structure that the input electrode and the output electrode are not overlapped with the control electrode should not be limited to the first control transistor TR3-G20 since transistors connected to the Q-node NQ (refer to FIGS. 5 and 6) may be applied with the stress caused by the high voltage applied to the Q-node NQ (refer to FIGS. 5 and 6). Therefore, the structure applied to the first control transistor TR3-G20 may be applied to all the transistors connected to the Q-node NQ (refer to FIGS. 5 and 6).

Referring to FIG. 9C, an input electrode SE3-G30 and an output electrode DE3-G30 of a first control transistor TR3-G30 are disposed to be spaced apart from each other. A channel area is defined between the input electrode SE3-G30 and the output electrode DE3-G30.

An etch stopper ES is disposed between the input electrode SE3-G30 and the output electrode DE3-G30 of the first control transistor TR3-G30. That is, the etch stopper ES covers the channel area defined between the input electrode SE3-G30 and the output electrode DE3-G30.

The structure of the input electrode SE3-G30, the output electrode DE3-G30, and the control electrode GE3-G of the first control transistor TR3-G30 except for the existence of the etch stopper ES are the same as one of those described with referent to FIGS. 8, 9A, and 9B.

The structure that the first control transistor TR3-G30 includes the etch stopper ES should not be limited to the first control transistor TR3-G30 since transistors connected to the Q-node NQ (refer to FIGS. 5 and 6) may be applied with the stress caused by the high voltage applied to the Q-node NQ (refer to FIGS. 5 and 6). Therefore, the structure applied to the first control transistor TR3-G20 may be applied to all the transistors connected to the Q-node NQ (refer to FIGS. 5 and 6).

Referring to FIG. 9D, a first control transistor TR3-G40 further includes a floating electrode FRT. The floating electrode FRT is disposed between an input electrode SE3-G40 and an output electrode DE3-G40 on an active layer AL3-G of the first control transistor TR3-G40. The floating electrode FRT is spaced apart from the input electrode SE3-G40 and the output electrode DE3-G40. The floating electrode FRT includes the same material as that of the input electrode SE3-G40 and the output electrode DE3-G40. The floating electrode FRT allows a length of the channel area formed in the active layer AL3-G of the first control transistor TR3-G to be lengthened. The horizontal electric field is formed between the floating electrode FRT and the input electrode SE3-G40 and between the floating electrode FRT and the output electrode DE3-G40. The vertical electric field is formed between the floating electrode FRT and the control electrode GE3-G In addition, the vertical electric field is formed between the input electrode SE3-G40 and the control electrode GE3-G and between the output electrode DE3-G40 and the control electrode GE3-G. Due to the vertical electric field formed between the floating electrode FRT and the control electrode GE3-G, the length of the channel area in the active layer may be lengthened.

The floating electrode FRT may serve as the output electrode with respect to the input electrode SE3-G40 and the floating electrode FRT may serve as the input electrode with respect to the output electrode DE3-G40. That is, this is the same as the structure in which two transistors are connected to each other in series. As described above, the structure in which the floating structure FRT is disposed between the input electrode SE3-G40 and the output electrode DE3-G40 is equivalent to the structure in which the transistors are connected to each other in series while the control electrodes of the transistors are connected to each other.

The structure of the input electrode SE3-G40, the output electrode DE3-G40, and the control electrode GE3-G of the first control transistor TR3-G40 except for the existence of the floating electrode FRT are the same as one of those described with referent to FIGS. 8, 9A, and 9B. Although the exemplary embodiments of the present inventive concept have been described, it is understood that the present inventive concept should not be limited to these exemplary embodiments but various changes and modifications can be made by one ordinary skilled in the art within the spirit and scope of the present inventive concept as hereinafter claimed.

What is claimed is:

1. A gate driving circuit comprising:
a plurality of stages applying gate signals to gate lines of a display panel, an i-th stage (i is a natural number equal to or greater than 2) among the stages comprising:
a Q-node controlling an output of a gate signal of the i-th stage or a carry signal of the i-th stage;
output transistors each outputting the gate signal or the carry signal of the i-th stage in accordance with a voltage level of the Q-node; and
a plurality of driving transistors connected to the Q-node to control the voltage level of the Q-node, wherein a first driving transistor of the driving transistors comprises a first control electrode, a first active layer, a first input electrode, and a first output electrode, and at least one of the first input electrode and the first output electrode is not overlapped with the first control electrode.

2. The gate driving circuit of claim 1, wherein the first input electrode of the first driving transistor is disposed not to overlap with the first control electrode and the first output electrode of the first driving transistor is disposed to overlap with the first control electrode.

3. The gate driving circuit of claim 1, wherein the first input electrode of the first driving transistor is disposed to overlap with the first control electrode and the first output electrode of the first driving transistor is disposed not to overlap with the first control electrode.

4. The gate driving circuit of claim 1, wherein the first input electrode and the first output electrode of the first driving transistor are disposed not to overlap with the first control electrode.

5. The gate driving circuit of claim 1, wherein the first output electrode and the first input electrode are spaced apart from each other by a predetermined distance to define a channel area, and the first driving transistor further comprises an etch stopper to cover the channel area.

6. The gate driving circuit of claim 1, wherein the first driving transistor further comprises a floating electrode disposed between the first output electrode and the first input electrode and spaced apart from the first output electrode and the first input electrode.

7. The gate driving circuit of claim 1, wherein the first driving transistor is connected between an input terminal, which is applied with the carry signal output from the (i−1)th stage, and the Q-node in a diode form to apply the carry signal output from the (i−1)th stage to the Q-node.

8. The gate driving circuit of claim 7, wherein the first control electrode and the first input electrode of the first driving transistor are commonly receive the carry signal output from the (i−1)th stage, the first output electrode is connected to the Q-node, the first input electrode is disposed to overlap with the first control electrode, and the first output electrode is disposed not to overlap with the first control electrode.

9. The gate driving circuit of claim 7, wherein a second driving transistor of the driving transistors comprises a second control electrode, a second active layer, a second input electrode, and a second output electrode and applies a reference voltage applied to the second input electrode to the Q-node connected to the second output electrode in response to the carry signal output from an (i+1)th stage and applied to the second control electrode, and at least one of the second input electrode and the second output electrode is not overlapped with the second control electrode.

10. The gate driving circuit of claim 9, wherein a third driving transistor of the driving transistors comprises a third control electrode, a third active layer, a third input electrode, and a third output electrode and applies the reference voltage applied to the third input electrode to the Q-node connected to the third output electrode in response to a switching signal generated by a clock signal applied to the third control electrode, and at least one of the third input electrode and the third output electrode is not overlapped with the third control electrode.

11. A display device comprising:
a display panel comprising a plurality of pixel rows; and
a gate driving circuit comprising a plurality of stages connected to each other one after another, an i-th stage (i is an integer number equal to or greater than 2) among the stages, which applies a gate signal to an i-th pixel row, comprising:
a first output part turned on or off in response to an electric potential of a Q-node to generate the gate signal from a clock signal, which is applied to a gate output terminal;
a control part controlling the electric potential of the Q-node;
a first pull-down part pulling down a voltage of the gate output terminal to a first low voltage after the gate signal is outputted;
a first holding part maintaining the gate output terminal at the first low voltage after the voltage of the gate output terminal is lowered to the first low voltage; and
an inverter part controlling an operation of the first holding part,
wherein a pixel-transistor of the i-th pixel row comprising:
a pixel control electrode;
a pixel output electrode; and
a pixel input electrode, the pixel output electrode and the pixel input electrode being symmetrically disposed with respect to the pixel control electrode, and
wherein at least one driving transistor among driving transistors connected to the Q-node comprising:
a driving control electrode;
a driving output electrode; and
a driving input electrode, the driving output electrode and the driving input electrode being asymmetrically disposed with respect to the driving control electrode.

12. The display device of claim 11, wherein at least one of the driving input electrode and the driving output electrode is not overlapped with the driving control electrode.

13. The display device of claim 11, wherein the driving input electrode is disposed not to overlap with the driving control electrode and the driving output electrode is disposed to overlap with the driving control electrode.

14. The display device of claim 11, wherein the driving input electrode is disposed to overlap with the driving control electrode and the driving output electrode is disposed not to overlap with the driving control electrode.

15. The display device of claim 11, wherein the driving output electrode and the driving input electrode of the driving transistor are spaced apart from each other by a predetermined distance to define a channel area, and the driving transistor further comprises an etch stopper to cover the channel area.

16. The display device of claim 11, wherein the driving transistor further comprises a floating electrode disposed between the driving output electrode and the driving input electrode and spaced apart from the driving output electrode and the driving input electrode.

17. The display device of claim 11, wherein the i-th stage further comprises a second output part turned on or off in response to the electric potential of the Q-node to generate the carry signal from the clock signal, which is applied to a carry output terminal.

18. The display device of claim 17, wherein the i-th stage further comprises a second pull-down part lowering a voltage of the carry output terminal to a second low voltage after the carry signal is outputted.

19. The display device of claim 18, wherein the second low voltage has an electric potential level lower than an electric potential level of the first low voltage.

20. The display device of claim 19, wherein the i-th stage further comprises a second holding part maintaining the voltage of the carry output terminal at the second low voltage after the voltage of the carry output terminal is lowered to the second low voltage.
